(19) United States
(12) Patent Application Publication
(10) Pub. No.: US 2005/0048204 A1
(43) Pub. Date: Mar. 3, 2005

(54) Method for the fabrication of silicon nitride, silicon oxynitride, and silicon oxide films by chemical vapor deposition

(76) Inventors: Christian Dussarrat, Ibaraki, (JP); Eri Tsukada, Ibaraki (JP); Jean-Marc Girard, Paris (FR)

Correspondence Address: Air Liquide;Intellectual Property Department, 2700 Post Oak Blvd, Suite 1800, Houston, TX, 77056, US

(21) Appl. No.: 10/497,191

(22) PCT Filed: Jul. 26, 2002
(86) PCT No.: PCT/IB02/02910

(30) Foreign Application Priority Data
Nov. 30, 2001 (JP) 2001-367130

(51) Int. Cl. C23C 16/00

(52) U.S. Cl. 427/248.1

(57) ABSTRACT

At least one compound selected from the group consisting of silane compounds with the formulas Sᵢ(NHRᵢ)₄ and SiH(NHRᵢ)₃ (each Rᵢ in each of the preceding formulas is independently selected from C₁ to C₄ hydrocarbyl) is used as a precursor for silicon nitride, silicon oxynitride, and silicon oxide films.

This invention relates to a method for fabricating silicon nitride, silicon oxynitride, and silicon oxide films by chemical vapor deposition (CVD).

Silicon nitride has excellent barrier properties and an excellent oxidation resistance and for this reason is used in numerous applications in the fabrication of microelectronic devices, for example, for hard mask layers, etch-stop layers, barrier layers, gate dielectric layers, and ONO stacks.

Plasma-enhanced CVD (PECVD) and low-pressure CVD (LPCVD) are the main methods currently used to form silicon nitride films.

In PECVD methods, a silicon source (typically a silane) and a nitrogen source (typically ammonia, but most recently nitrogen) are introduced between a pair of parallel flat-plate electrodes and a plasma is generated from the silicon source and nitrogen source at low temperatures (about 300° C.) and intermediate pressures (0.1 to 5 Torr) by the application of high-frequency energy between the two electrodes. Active silicon species and active nitrogen species in the generated plasma react with each other with the formation of a silicon nitride film. The silicon nitride films produced by PECVD generally do not have a stoichiometric composition and are also hydrogen-rich and as a result have a low film density and a high etch rate and are of poor quality.

Thermal LPCVD employs low pressures (0.1 to 2 Torr) and high temperatures (750° C. to 900° C.) and produces silicon nitride films of a quality superior to that of the silicon nitride films produced by PECVD. At the present time this LPCVD method generally employs the reaction of dichlorosilane (DCS, SiH₂Cl₂) and gaseous ammonia. However, ammonium chloride in the form of a white deposit is produced as a by-product in this reaction in the prior-art LPCVD methods; this ammonium chloride can accumulate in and clog the exhaust line of the reaction apparatus. Moreover, this method provides a slow silicon nitride deposition rate and is therefore unsuitable for back-end-of-line (BEOL) applications since the reaction must be carried out at high temperatures in order to obtain acceptable deposition rates (>10 Å/min). High-temperature processes are also troublesome with regard to precise control of the dopant distribution profile in silicon films.

A number of precursors, vide infra, have been introduced to date in order to solve the drawbacks identified above, but none of these precursors solves the aforementioned drawbacks completely and various issues remain.

The use of hexachlorodisilane (HCDS, Si₂Cl₆) in place of the usual dichlorosilane is known as one method for effecting reaction at low temperatures. Si₂Cl₆ reacts with ammonia at relatively low temperatures (around 600° C.). This method, however, produces ammonium chloride in an amount at least equal to that produced by methods using ordinary dichlorosilane, which makes it necessary to periodically clean the reaction apparatus and exhaust line in order to remove the ammonium chloride and also creates substantial risk of contamination of the substrate with particles of ammonium chloride.

A method that uses ammonia and bis(tert-butylamino)silane SiH₂(NHtBu)₂ (BTBAS, tBu=tert-butyl) is disclosed in U.S. Pat. No. 5,874,368. This method can also produce silicon nitride films at lower temperatures than for the use of ordinary dichlorosilane and ammonia. Moreover, this method is not accompanied by the production of ammonium chloride since BTBAS does not contain chlorine. However, since the silicon-hydrogen bond is difficult to cleave (SiH bond energy=318 kJ/mol), films produced using BTBAS are hydrogen-rich.

U.S. Pat. No. 5,234,869 discloses a method that uses compounds with the formula SiHₓ(NMe₂)₄₋ₓ(Me=methyl) as a chlorine-free (i.e., non-ammonium chloride-producing) precursor for silicon nitride. Silicon nitride is produced in this method by supplying a compound SiHₓ(NMe₂)₄₋ₓ along with ammonia to LPCVD. LPCVD methods that use SiH(NMe₂)₃ are disclosed by Levy et al., M. Mater. Res., 11, 1483, 1996 and Boudreau et al., Mater. Res. Soc., Symp. Proc., 300, 183, 1993. A PECVD method using the same compound is disclosed by Aoki et al., Proc. of the 4th ISSP, 345, 1997. It is known, however, that carbon occurs in high proportions in the films produced using these compounds because these precursors contain a substituent of the type —NR₁, R₂ in which R₁ and R₂ are both alkyl, such as the —NMe₂ group. A PECVD method using the compound SiH₂tBu₂ is disclosed by Grow et al., Mater. Lett., 23, 187, 1995. Aside from the fact that this method is not an LPCVD method, it produces film with a high carbon content because the SiC bond is already present in the precursor. Methods using azidosilane as a precursor are disclosed in U.S. Pat. Nos. 4,992,299, 4,992,306, and 5,013,690. However, the azidosilanes used in these methods, such as SiEt₃N₃ (Et=ethyl), contain carbon directly bonded to silicon, which results in the admixture of high levels of silicon carbide in the silicon nitride films produced by these methods. The presence of high levels of carbon in a film product, as is the case for the methods under consideration, impairs the insulating performance of the film.

U.S. Pat. Nos. 4,200,666 and 4,569,855 also disclose methods for silicon nitride deposition that use chlorine-free precursors, but these methods are not LPCVD methods.

The issues identified above can also occur when silicon oxide films and silicon oxynitride films—which have the same properties and applications as silicon nitride films—are fabricated using the prior-art precursors discussed above.

The problem addressed by this invention, therefore, is to provide a method that can produce low-hydrogen, low-carbon silicon nitride, silicon oxynitride, and silicon oxide films by LPCVD technology and that can do so even at low temperatures and without producing ammonium chloride.

As a result of extensive investigations directed to solving the problems identified above, the inventors discovered that low-hydrogen, low-carbon silicon nitride, silicon oxynitride, and silicon oxide films could be produced by LPCVD even at low temperatures and without producing ammonium chloride by admitting a silane compound with the formula Si(NHRᵢ)₄ and/or SiH(NHRᵢ)₃ (each Rᵢ in each of the preceding formulas is independently selected from C₁ to C₄ hydrocarbyl) and another specific gas into the reaction chamber. This invention is based on this discovery.

Thus, according to a first feature of this invention, a method for fabricating silicon nitride films by chemical vapor deposition is provided, said method being characterized by forming a silicon nitride film on a substrate by introducing at least one silicon nitride precursor selected from the group consisting of silane compounds with the formulas Si(NHRᵢ)₄ and SiH(NHRᵢ)₃ (each Rᵢ in each of the preceding formulas is independently selected from C₁ to C₄ hydrocarbyl) and a second reaction gas selected from the group consisting of ammonia, hydrazine, alkylhydrazine compounds, and hydrogen azide, into a reaction chamber loaded with at least one substrate and

heating to a temperature of 300° C. to 900° C. while maintaining the chamber at a pressure from 0.05 Torr to atmospheric pressure.

According to a second feature of this invention, a method for fabricating silicon oxynitride films by chemical vapor deposition is provided, said method being characterized by forming a silicon oxynitride film on a substrate by introducing at least one silicon oxynitride precursor selected from the group consisting of silane compounds with the formulas Si(NHRᵢ)₄ and SiH(NHRᵢ)₃ (each Rᵢ in each of the preceding formulas is independently selected from C₁ to C₄ hydrocarbyl), at least one nitrogen-containing gas, and at least one oxygen-containing gas into a reaction chamber loaded with at least one substrate and

heating to a temperature of 300° C. to 900° C. while maintaining the chamber at a pressure from 0.05 Torr to atmospheric pressure.

The nitrogen-containing gas used in this method is preferably selected from the group consisting of ammonia, hydrazine, alkylhydrazine compounds, hydrogen azide, nitric oxide, nitrogen dioxide, and nitrous oxide. The oxygen-containing gas used in this method is preferably selected from the group consisting of nitric oxide, nitrogen dioxide, nitrous oxide, oxygen, ozone, hydrogen peroxide, and H₂O.

According to a third aspect of this invention, a method for fabricating silicon oxide films by chemical vapor deposition is provided, said method being characterized by forming a silicon oxide film on a substrate by

introducing at least one silicon oxide precursor selected from the group consisting of silane compounds with the formulas Si(NHRᵢ)₄ and SiH(NHRᵢ)₃ (each Rᵢ in each of the preceding formulas is independently selected from C₁ to C₄ hydrocarbyl) and at least one oxygen-containing gas into a reaction chamber loaded with at least one substrate and

heating to a temperature of 300° C. to 900° C. while maintaining the chamber at a pressure from 0.05 Torr to atmospheric pressure.

The oxygen-containing gas used in this method is preferably selected from the group consisting of nitric oxide, nitrogen dioxide, nitrous oxide, oxygen, ozone, hydrogen peroxide, and H₂O.

The precursor used in this invention is preferably selected from the group consisting of tetrakis(ethylamino)silane, tris(ethylamino)silane, and tris(isopropylamino)silane.

### BRIEF DESCRIPTION OF DRAWINGS

FIG. 1 contains a graph of the relationship between the TEAS/ammonia molar ratio and the silicon nitride film growth rate.

FIG. 2 contains a graph of the temperature dependence of the silicon oxide film growth rate for the use of TEAS as precursor.

FIG. 3 contains the FTIR spectrum of TEAS.

FIG. 4 contains the FTIR spectrum of TriEAS.

FIG. 5 contains the FTIR spectrum of TIPAS.

FIG. 6 contains a graph of the temperature dependence of the silicon nitride film growth rate for the use of TriEAS as precursor.

FIG. 7 contains a graph of the temperature dependence of the silicon nitride film growth rate for the use of TIPAS as precursor.

### BEST MODE FOR CARRYING OUT THE INVENTION

This invention is explained in greater detail hereinbelow.

This invention, which relates to a method for forming silicon nitride, silicon oxynitride, and silicon oxide films on substrates by CVD, uses specific compounds as precursors for these films.

The precursors used by this invention comprise silane compounds with the formulas Si(NHRᵢ)₄ and SiH(NHRᵢ)₃. Each Rᵢ in each of these formulas is independently selected from C₁ to C₄ hydrocarbyl. This C₁ to C₄ hydrocarbyl encompasses alkyl and vinyl. The C₁ to C₄ alkyl encompasses methyl, ethyl, propyl, isopropyl, butyl, and tert-butyl. The inventive precursors do not contain chlorine and therefore do not generate ammonium chloride as a by-product. They also enable the generation, even at low temperatures (550° C. to 700° C.), of CVD films having low hydrogen and carbon contents. The inventive precursors can provide a lower carbon content in the CVD film product than in the prior art because the inventive precursors lack carbon directly bonded to silicon and because their substituent group, being a secondary amine (—NHR), has a low carbon content. The inventive precursors can also provide a low hydrogen content in the CVD film because they contain little hydrogen directly bonded to Si.

The silane compounds Si(NHRᵢ)₄ used by this invention, because they lack hydrogen directly bonded to Si, provide even smaller hydrogen levels in the CVD film product. The optimal precursor among the compounds Si(NHRᵢ)₄ is tetrakis(ethylamino)silane (TEAS or Si(NHEt)₄). This compound is easy to synthesize (Narsavage et al., Chem. Mater., 721, 3, 1991) and is volatile (vapor pressure at 25° C.=1.3 Torr). Moreover, this compound, due to its small steric effects and because its ethylamino group is easily eliminated, reacts readily with the nitrogen-containing gas, such as ammonia, and for this reason can form a silicon nitride, silicon oxynitride, or silicon oxide film by LPCVD at low temperatures (550° C. to 700° C.).

The preferred precursors among the silane compounds SiH(NHRᵢ)₃ used by this invention are tris(ethylamino)silane (TriEAS, SiH(NHEt)₃) and tris(isopropylamino)silane (TIPAS, SiH(NiPr)₃ where iPr=isopropyl).

In accordance with this invention, at least one inventive precursor is introduced into a reaction chamber loaded with at least one substrate in order to form a silicon nitride film on the substrate, particularly on a semiconductor substrate such as a silicon substrate. A second reaction gas, selected from the group consisting of ammonia, hydrazine, alkylhydrazine compounds, and hydrogen azide, is also supplied to the reaction chamber along with the precursor.

To carry out the intended reaction, the substrate is heated to 300° C. to 900° C. while the reaction chamber is maintained at a pressure from 0.05 Torr to atmospheric pressure. The pressure within the reaction chamber is preferably 0.1 to 5 Torr, and the CVD reaction temperature is preferably 550° C. to 700° C. The molar ratio between the silicon nitride precursor and the second reaction gas will generally be 1:1 to 1:20 and is preferably 1:3 to 1:10. The inventive silicon nitride film precursor and the nitrogen-containing second reaction gas react under these conditions with the formation of a silicon nitride film on the substrate.

An inert gas, e.g., nitrogen or a rare gas such as argon, can also be introduced into the reaction chamber. The introduction of an inert gas can improve the film properties of a CVD film, such as its uniformity. An inert gas may also be used during vaporization of the inventive precursor. For example, a precursor of this invention can be entrained in an inert gas by bubbling the inert gas through the liquid precursor and the vapor-phase precursor can then be supplied in this form to the reaction chamber. Alternatively, when the liquid precursor of the invention is to be volatilized using a vaporizer, an inert gas is also introduced into the vaporizer and the vaporized precursor is then fed to the reaction chamber along with the inert gas.

The following are introduced into the reaction chamber when a silicon oxide film is to be deposited in accordance with this invention on a substrate: precursor according to this invention as described above in relation to silicon nitride film deposition, dilution gas on an optional basis, and, in place of the second reaction gas, at least one oxygen-containing gas. This oxygen-containing gas should also be free of chlorine and is preferably selected from the group consisting of nitric oxide, nitrogen dioxide, nitrous oxide, oxygen, ozone, hydrogen peroxide, and H₂O. The molar ratio between the inventive precursor and the oxygen-containing gas is preferably 10:1 to 1:10. Precursor according to this invention can result in the deposition of silicon oxide at lower temperatures since the inventive precursor is more reactive with the oxygen-containing gas than the dialkylaminosilanes that are typically used. In this case the molar ratio between the precursor and oxygen-containing gas is preferably 1:100 to 1:2. A pure, nitrogen-free silicon oxide film can be obtained by increasing the proportion of oxygen-containing gas introduced into the reaction chamber relative to the inventive silicon nitride precursor. Nitrogen-free gases such as H₂O, hydrogen peroxide, ozone, and oxygen are optimal oxygen-containing gases for the purpose of producing nitrogen-free silicon oxide films. In this case a molar ratio between the precursor and oxygen-containing gas of 1:100 to 1:10 is preferably used. A silicon oxide film is formed on the substrate by reacting the inventive precursor with the oxygen-containing gas under the pressure and temperature conditions already described above with reference to silicon nitride films.

Precursor according to this invention, nitrogen-containing gas, at least one oxygen-containing gas, and optionally dilution gas are introduced when deposition of a silicon oxynitride film is desired. The nitrogen-containing gas used here can be the second reaction gas described above. The oxygen-containing gas used here can be an oxygen-containing gas as described above in relation to the fabrication of silicon oxide films. When the oxygen-containing gas does not contain nitrogen, as is the case, for example, with oxygen, ozone, hydrogen peroxide, and H₂O, the molar ratio between the inventive precursor and nitrogen-containing gas is preferably 10:1 to 1:50 and the molar ratio between the precursor and the oxygen-containing gas is preferably 50:1 to 1:10. The additional use of a nitrogen-containing gas as a nitrogen source may be omitted when the oxygen-containing gas also contains nitrogen. For example, when the oxygen-containing gas is nitric oxide, nitrogen dioxide, or nitrous oxide, the molar ratio between the inventive precursor and the oxygen- and nitrogen-containing gas is preferably 1:1 to 1:50 and more preferably is 1:1 to 1:5. A silicon oxynitride film is formed on the substrate by reacting the inventive precursor with the nitrogen-containing gas and oxygen-containing gas under the pressure and temperature conditions described in relation to silicon nitride films.

This invention is explained in greater detail in the following through working examples, but this invention is not limited to these examples.

### EXAMPLE 1

Formation of Silicon Nitride Films using TEAS

Silicon nitride films were formed by LPCVD using TEAS as the silicon nitride precursor and ammonia as the nitrogen-containing gas.

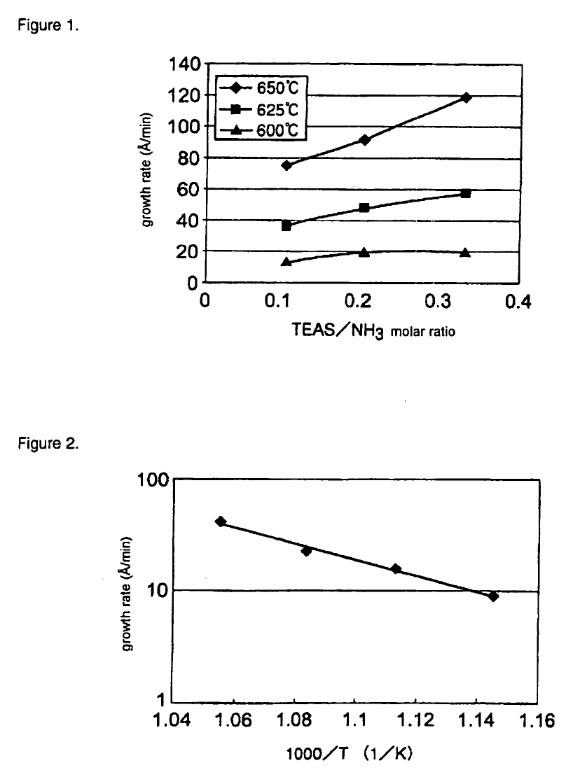

FIG. 1 contains a graph of the relationship between the TEAS/NH₃ molar ratio and the growth rate; the TEAS/ammonia flow rate ratio (molar ratio) is plotted on the x-axis and the silicon nitride film growth rate is plotted on the y-axis. The data in the graph were acquired by measuring the growth rate at TEAS/NH₃ molar ratios from 0.1 to 0.33 at reaction temperatures of 600° C., 625° C., and 650° C. The pressure within the chamber was maintained at 0.2 Torr in these measurements. In all cases a satisfactory growth rate (>10 Å/min) was obtained at lower temperatures (600° C. to 650° C.) than the temperatures of 750° C. to 900° C. used in conventional thermal LPCVD methodologies.

Table 1 reports the analytical values given by secondary ion mass spectroscopy (SIMS) for the carbon and hydrogen impurities in silicon nitride films deposited using a TEAS precursor. The temperature and pressure conditions for each reaction are also reported in Table 1.

TABLE 1
Impurity levels in silicon nitride films,
as obtained by secondary ion mass spectroscopy

| compound | TEAS | TEAS |
|---|---|---|
| temperature | 600° C. | 650° C. |
| pressure | 0.2 Torr | 0.2 Torr |
| SIMS analysis | | |
| hydrogen content (atoms/cm³) | 6 × 10²¹ | 7 × 10²¹ |
| carbon content (atoms/cm³) | 2.5 × 10²¹ | 4 × 10²¹ |

### EXAMPLE 2

Formation of Silicon Oxide Films using TEAS

Silicon oxide films were formed by LPCVD using oxygen as the oxygen-containing gas and using TEAS as precursor.

FIG. 2 contains a graph of the temperature dependence of the growth rate, in which the reciprocal of the reaction temperature is plotted on the x-axis and the logarithm of the silicon oxide film growth rate is plotted on the y-axis. The data in this graph were acquired by measurements carried out at different substrate temperatures from 600° C. to 675° C. at a TEAS partial pressure of 60 mTorr and a TEAS/oxygen flow rate ratio (molar ratio) of 1:5. Since the growth rate reaches 10 Å/min at a reaction temperature of 600° C., an acceptable growth rate is obtained at temperatures lower than in standard thermal LPCVD methodologies.

The silicon oxide film obtained in this example had a refractive index of 1.6 (versus 1.48 for thermal silicon oxide), which indicated that this film contained some nitrogen (oxynitride).

### EXAMPLE 3

Formation of Silicon Nitride Films using TriEAS and TIPAS

Synthesis of TriEAS and TIPAS

TriEAS and TIPAS, which are preferred precursors in accordance with this invention, were synthesized in preparation for the fabrication of silicon nitride films by LPCVD using these precursors. The starting reagents were trichlorosilane (TCS) and amine in both cases. Ethylamine was used as the amine in the case of TriEAS synthesis, while isopropylamine was used as the amine in the case of TIPAS synthesis. Synthesis was carried out as follows in both cases.

The cooled amine was added, in an amount in excess to the TCS used, to pentane (solvent) cooled to 0° C. to prepare an amine solution. TCS was added dropwise to the 0° C. amine solution. Stirring was carried out for an additional 2 hours at 0° C. after the completion of addition, followed by stirring for 15 hours at room temperature. The NH₃RCl by-product (R=ethyl or isopropyl in the syntheses under consideration) was then removed by filtration followed by elimination of the pentane solvent in vacuo. The excess amine and synthesized trisalkylaminosilane were finally fractionally distilled at a temperature not exceeding 50° C. A temperature not exceeding 50° C. was employed here due to the occurrence of partial polymerization when higher temperatures are used.

The purity of the synthesized substances was confirmed by gas chromatography. Measurement of the chlorine concentration in the products by ion chromatography gave trace values. The results from measurement of the synthesized substances by proton-NMR and ¹³C-NMR are collected in Table 2. Measured values for TEAS and literature values for ethylamine (NH₂Et) and isopropylamine (NH₂iPr) (source: The Aldrich Library of ¹³C and ¹H FT-NMR Spectra of NH₂Et) are also reported for reference.

TABLE 2
Measurement results from proton-NMR and ¹³C-NMR

| assignment | Si(NHEt)₄ | SiH(NHEt)₃ | SiH(NHiPr)₃ | NH₂Et | NH₂iPr |
|---|---|---|---|---|---|
| —NH₍₂₎ | 0.39 | 0.8 | 0.67 | 3.65 | 1.22 |
| —CH₃ | 1.06 (tr) | 1.07 (tr) | 1.07 (db) | 1.10 (tr) | 1.07 (db) |
| —CH₍₂₎ | 2.85 (quin) | 2.81 (quin) | 3.16 (sept) | 2.73 (quin) | 3.10 (sept) |
| SiH | | 4.5 | 4.42 | | |
| —CH₍₂₎— | 20.7 | 20.1 | 27.76 | 18.8 | 26.2 |
| (CH3)₍₂₎ | 36.2 | 35.7 | 42.2 | 36.7 | 42.8 |

unit: ppm in all cases

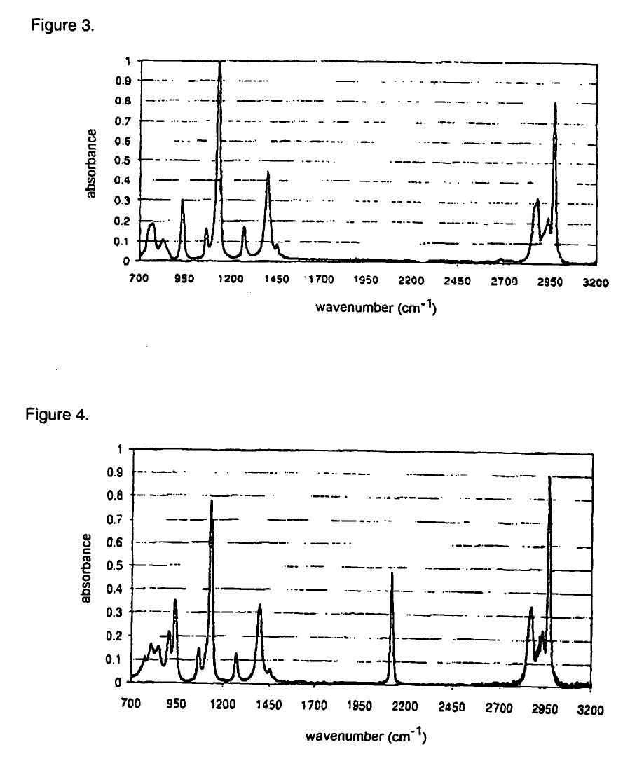

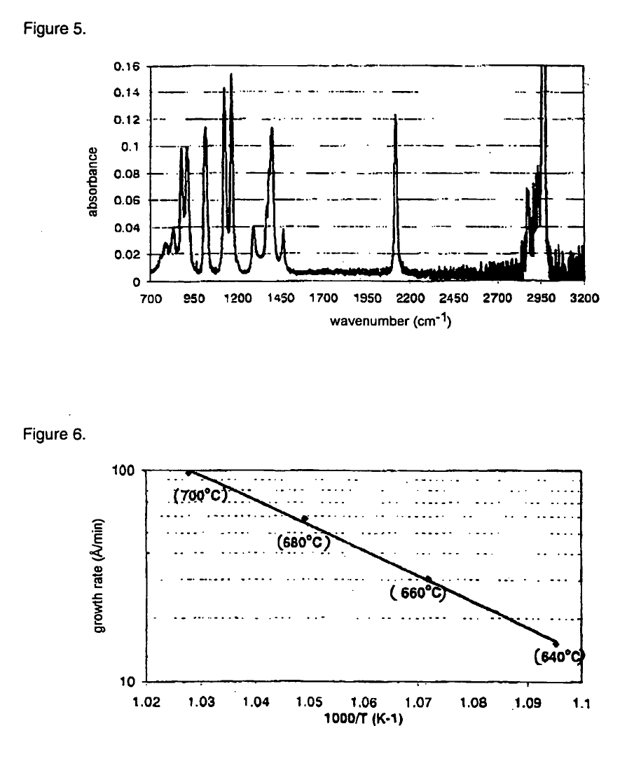

The molecular structures of the synthesized substances were also confirmed by gas-phase FTIR spectroscopy. The FTIR spectrum of TEAS is given in FIG. 3, the FTIR spectrum of TriEAS is given in FIG. 4, and the FTIR spectrum of TI PAS is given in FIG. 5.

Silicon Nitride Film Formation

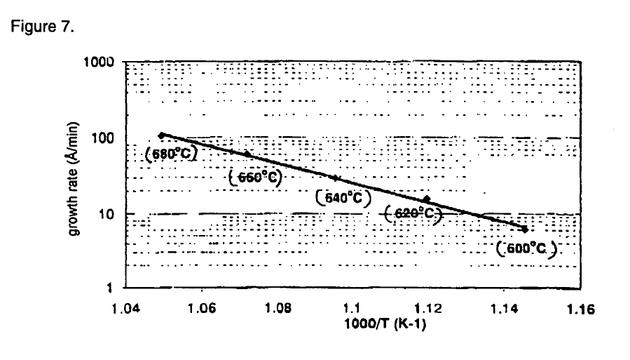

Silicon nitride films were fabricated by LPCVD using ammonia as the nitrogen-containing gas and TriEAS or TIPAS for the silicon nitride precursor. FIGS. 6 and 7 contain graphs showing the temperature dependence of the growth rate, in which the reciprocal of the reaction temperature is plotted on the x-axis and the logarithm of the silicon nitride film growth rate is plotted on the y-axis.

In the experiment plotted in FIG. 6, the growth rate was measured during silicon nitride film formation at reaction temperatures of 640 to 700° C. using TriEAS as precursor. In this case the precursor TriEAS was supplied using a bubbler. To accomplish this, nitrogen gas (=inert gas) was introduced into a bubbler and was bubbled through liquid TriEAS and TriEAS vapor entrained in the nitrogen gas was introduced into the reaction chamber. The nitrogen flow rate was 30 sccm and the pressure in the bubbler, as measured using a Baratron pressure sensor, was 5 Torr. The TriEAS flow rate was estimated at approximately 1 sccm. The ammonia flow rate was 25 sccm and the pressure in the reaction chamber was 1 Torr. The activation energy Ea obtained from the graph in FIG. 6 was 54 kcal/mol.

In the experiment plotted in FIG. 7, the growth rate was measured during silicon nitride film formation at temperatures in the reaction chamber of 600 to 680° C. using TIPAS as precursor. The experimental method and conditions were the same as for the TriEAS experiment described above, with the exception that the pressure within the bubbler was 10 Torr. The TIPAS flow rate was estimated at approximately 1 sccm. The activation energy Eₐ was 60 kcavmol.

The composition of each of the silicon nitride film products was measured using an Auger spectrophotometer. Si_{0.75}N was obtained when TriEAS was used as the precursor, while Si_{0.85}N was obtained when TIPAS was used as the precursor.

The amount of carbon and hydrogen impurity in silicon nitride film deposited using TIPAS as precursor was also analyzed by SIMS. The reaction temperature was 600° C. and the pressure was 1 Torr. The results were as follows: carbon content=1.04×10²² atoms/cm³, hydrogen content=1.18×10²² atoms/cm³.

The preceding results show that the use of TriEAS and TIPAS as precursors enabled the fabrication of high-quality silicon nitride films at acceptable growth rates at lower temperatures than in prior-art LPCVD processes.

### INDUSTRIAL APPLICABILITY

The method of this invention enables the low-temperature production by LPCVD of silicon nitride, silicon oxynitride, and silicon oxide films that contain little hydrogen or carbon. Moreover, the inventive method achieves this outcome without producing ammonium chloride.

1-12. (cancelled).

13 (cancelled).

14. The method of claim 25, wherein said precursor comprises at least one member selected from the group consisting of:
a) tetrakis(ethylamino)silane;
b) tris(ethylamino)silane; and
c) tris(isopropylamino)silane.

15. The method of claim 25, further comprising introducing an inerting gas into said chamber.

16 (cancelled).

17. The method of claim 26, wherein said precursor comprises at least one member selected from the group consisting of:
a) tetrakis(ethylamino)silane;
b) tris(ethylamino)silane; and
c) tris(isopropylamino)silane.

18. The method of claim 26, wherein said nitrogen-containing gas comprises at least one member selected from the group consisting of:
a) ammonia;
b) hydrazine;
c) alkylhydrazine compounds;
d) hydrogen azide;
e) nitric oxide;
f) nitrogen dioxide; and
g) nitrous oxide.

19. The method of claim 26, wherein said oxygen-containing gas comprises at least one member selected from the group consisting of:
a) nitric oxide;
b) nitrogen dioxide;
c) nitrous oxide d) oxygen;
e) ozone;
f) hydrogen peroxide; and
g) H₂O.

20. The method of claim 26, further comprising introducing an inerting gas into said reaction chamber.

21 (cancelled).

22. The method of claim 27, wherein said precursor comprises at least one member selected from the group consisting of:
a) tetrakis(ethylamino)silane;
b) tris(ethylamino)silane; and
c) tris(isopropylamino)silane.

23. The method of claim 27, wherein said oxygen-containing gas comprises at least one member selected from the group consisting of:
a) nitric oxide;
b) nitrogen dioxide;
c) nitrous oxide;
d) oxygen;
e) ozone;
f) hydrogen peroxide; and
g) H₂O.

24. The method of claim 27, further comprising introducing an inerting gas into said chamber.

25. A method which may be used for fabricating a silicon nitride film by chemical vapor deposition, said method comprising:
a) introducing at least one first reaction gas comprising a silicon nitride precursor into a reaction chamber containing at least one substrate, wherein said precursor comprises at least one member selected from the group consisting of:
1) Si(NHRᵢ)₄, and
2) SiH(NHRᵢ)₃,
wherein each R1 represents a C₁ to C₄ hydrocarbyl;
b) introducing a second reaction gas into said chamber, wherein said second gas comprises at least one member selected from the group consisting of:
1) ammonia;
2) hydrazine;
3) alkylhydrazine compounds; and
4) hydrogen azide; and
c) heating said chamber to a temperature between about 300° C. to about 900° C., while maintaining a pressure in said chamber of about 0.05 Torr to about atmospheric pressure.

26. A method which may be used for fabricating a silicon nitride film by chemical vapor deposition, said method comprising:
a) introducing at least one first reaction gas comprising a silicon nitride precursor into a reaction chamber containing at least one substrate, wherein said precursor comprises at least one member selected from the group consisting of:
1) Si(NHRᵢ)₄, and
2) SiH(NHRᵢ)₃,
wherein each Rᵢ represents a C₁ to C₄ hydrocarbyl;
b) introducing at least one nitrogen-containing gas into said chamber;
c) introducing at least one oxygen-containing gas into said chamber; and
d) heating said chamber to a temperature between about 300° C. to about 900° C., while maintaining a pressure in said chamber of about 0.05 Torr to about atmospheric pressure.

27. A method which may be used for fabricating a silicon nitride film by chemical vapor deposition, said method comprising:
a) introducing at least one first reaction gas comprising a silicon nitride precursor into a reaction chamber containing at least one substrate, wherein said precursor comprises at least one member selected from the group consisting of:
1) Si(NHRᵢ)₄, and
2) SiH(NHRᵢ)₃,
wherein each Rᵢ represents a C₁ to C₄ hydrocarbyl;
b) introducing at least one oxygen-containing gas into said chamber; and
c) heating said chamber to a temperature between about 300° C. to about 900° C., while maintaining a pressure in said chamber of about 0.05 Torr to about atmospheric pressure.
